(19) United States
(12) Patent Application Publication
(10) Pub. No.: US 2007/0178750 A1
(43) Pub. Date: Aug. 2, 2007

(54) Flexible printed circuit having inter-lead ribs in a welding area

(75) Inventors: Wan-Ho Chung, Taipei County (TW); Po-Ching Chung, Kaohsiung County (TW); Chien-Chung Chen, Nan-Tou County (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/600,882

(22) Filed: Nov. 17, 2006

(30) Foreign Application Priority Data
Jan. 27, 2006 (TW) 95103620

(51) Int. Cl. H05K 1/00; H01R 12/24

(52) U.S. Cl. 439/495; 174/254

(57) ABSTRACT

An FPC structure includes a base board, at least two pads, an insulation layer and a rib. These pads are disposed on the base board. The insulation layer covers the base board and has a hollow opening for exposing the pads. The rib is set on the surface of the base board and located between two pads.

### FIELD OF THE INVENTION

The present invention relates to the welding structure of the flexible printed circuit (FPC), and more particularly to a lead structure that provides a flow-block rib between two adjacent leads (or fingers) in the welding area with a party printed circuit board so as to avoid possible short circuit in the FPC.

### BACKGROUND OF THE INVENTION

As the electric technology prospers, portable electric products such as cell phones, PDAs, digital cameras and LED molds become the mainstream products in the marketplace. A clear trend of those electric products in design is lightweight, thin, low-price, and a quality demand in fancy appearance and versatile functions.

To make the product versatile, equipping the product with optional peripherals such as the display screen, the secondary printed circuit board, the extension memory, and even a photograph mold or a network operation mold is an effective resort in diversifying the electric product.

In manufacturing the aforesaid electric products, a cable or an FPC is usually used for internal electrical connection through welding. Owing to the present electric products have the trend in lightweight, thin in thickness and small in size, the interior welding lead structure of the cable or the FPC is gradually made to be one with high lining density in an extreme limit area.

For the high lining density in the welding structure of the FPC or cable in the electric device, a short-circuit problem is usually met while a welding process slightly deviates from a standard setup, especially at the situation that a welding tin or grease is involved in the welding. Empirically, such a short-circuit problem is the major reason contributed to a low yield of welding the FPC or cable.

Referring to FIG. 1a and FIG. 1b, a frontage view and its section view along line aa′ of a welding structure 10 of a conventional FPC are respectively shown. As shown, the welding structure comprises a base board 100, an insulation layer 101, two pads 102 and a tin grease 103.

Generally, the surface of the base board 100 has a complicated circuit pattern. To enable the base board 100 to set up signal connection with other electrical elements, enough pads 102, more than two, are usually needed pads 102 at the end portion of circuit diagrams (however, two shown in the figure for symbolizations). As shown, these pads 102 are formed on the surface of the base board 100. Besides, to prevent the circuit diagrams from being damaged by the outside world, the surface of the base board 100 is layered by the insulation layer 101. The insulation layer 101 has a hollow opening 105 for exposing out the pads 102. Generally, the opening 102 exposes the adjacent pads 102 and the portion surface of thee base board 100 between the two pads 102. Before the FPC can be welded to the other FPC, these pads 102 should be spread by a predetermined amount of the tin grease 103.

Referring to FIGS. 1c and 1d, a frontage view of a conventional welding structure of the FPC with another FPC on a top welding position and a cross sectional view along line bb′ of FIG. 1c are shown, respectively.

As shown, after the tin grease 103 on the pads 102 melts, the on-top FPC 110 will be pressed onto the welding structure 10 of the bottom FPC 101. In the FPC 110, corresponding welding structure 11 includes a base board 110, and the pads 112 formed under the base board 110 to facing the mating pads 102. After being pressed to firm, the pads 112 of the welding structure 11 will be fixed, through tin grease 103, to the corresponding pads 102.

Because the pitch of the adjacent pads 102 is quite small, the melting tin grease 103 may outflow to the surface of the base board 100 and to make short circuit the adjacent pads 102 as shown in FIG. 1d.

In some other designs, an opening of the insulation layer may be included to expose the pads of the FPC. Referring to FIGS. 2c˜2d, the design of opening on the FPC to expose the pads is shown. Also, referred to FIGS. 2a and 2b, a frontage and section views of the welding structure of the FPC of FIGS. 2c and 2d, matching another FPC, are shown, respectively; in which FIG. 2b is a cross sectional view of FIG. 2a along line cc′. As shown, the welding structure comprises a base board 200, an insulation layer 201, two pads 202 and a tin grease 203.

On the base board 200, a great quantity of circuit diagrams may be included. To avoid possible short circuit in welding, the insulation layer 201 is layered on top of the base board 200, but leaves separate hollow openings 205 to expose the pads 202.

As shown in FIGS. 2c and 2d, after the tin grease 203 on the pads 202 melts, another FPC can be pressed onto the welding structure 20. Similarly, the top FPC comprises a base board 210 and the pads 212 formed on the bottom surface of the base board 210. Through the welding processing and the tin grease 203, the pads 212 of the lower welding structure can be fixed to the corresponding upper pads 202.

For the pitch between the adjacent pads 202 is still quite small, the melting tin grease 203, though staying only on the insulation layer 201, may still overflow sideward to make short circuit between the pads 202, as shown in FIG. 2d.

Obviously, with or without the insulation layer 201, overflowing of the tin grease and the consequent short-circuiting between pads may still exist in the conventional designs of the FPC. In order to reduce short circuiting of the FPC and to raise the yield in wielding FPCs, solving the overflow tin grease is definitely a very impartment aspect.

### SUMMARY OF THE INVENTION

The object of the present invention is to provide an FPC that can prevent the adjacent pads from short circuiting. In the invention, a rib is included to resist overflowing of the melting tin grease between the pads, and thus possible short circuit between two pads can be avoided.

A welding structure of the FPC according to the present invention comprises an FPC, a first pad, a second pad and a rib. The first pad is disposed on the FPC, and the second pad is disposed also on the FPC but side to the first pad. The rib disposed on the FPC sets between the first pad and the second pad.

In another preferred embodiment of the present invention, a structure of the FPC comprises a base board, at least two pads, an insulation layer and a rib. These pads are disposed on the base board. The insulation layer covering the base board has a hollow opening to expose the two pads. The rib is also disposed on the surface of base board to separate in between the two pads.

In the present invention, the rib and the insulation layer can be made of the same material such as a Polyimide material.

In the present invention, the thickness of the rib is above 25 μm, and is required to be larger than the thickness of the insulation layer. Also, the distance of the rib and the pad is larger than 0.1 mm.

In the present invention, the FPC can be a flexible FPC and can be applied to a power line of an electrical product. The electrical product is an LCD and the FPC is connected to the light source of the LCD monitor.

In the present invention, the rib and the insulation layer can be manufactured at the same time.

### BRIEF DESCRIPTION OF THE DRAWINGS

Other features and advantages of this invention will become more apparent in the following detailed description of the preferred embodiments of this invention, with reference to the accompanying drawings, in which:

FIG. 1a is a frontage view of a conventional welding structure of the FPC;

FIG. 1b is a cross sectional view of FIG. 1a along line aa′;

FIG. 1c shows, in a frontage view, another FPC welded on top to the FPC of FIG. 1a;

FIG. 1d is a cross sectional view of FIG. 1c along line bb′;

FIG. 2a is a frontage view of another conventional welding structure of the FPC;

FIG. 2b is a cross sectional view of FIG. 2a along line cc′;

FIG. 2c shows, in a frontage view, another FPC welded on top to the FPC of FIG. 2a;

FIG. 2d is a cross sectional view of FIG. 2c along line dd′;

FIG. 3a is a frontage view of a preferred embodiment of a welding structure of a FPC in accordance with the present invention;

FIG. 3b is a cross sectional view of FIG. 3a along line ee′;

FIG. 3c shows, in a frontage view, another FPC welded on top to the FPC of FIG. 3a;

FIG. 3d is a cross sectional view of FIG. 3c along line ff′;

FIG. 4a is a frontage view of another embodiment of a welding structure of a FPC in accordance with the present invention;

FIG. 4b is a cross sectional view of FIG. 4a along line gg′;

FIG. 4c shows, in a frontage view, another FPC welded on top to the FPC of FIG. 4a; and

FIG. 4d is a cross sectional view of FIG. 4c along line hh′.

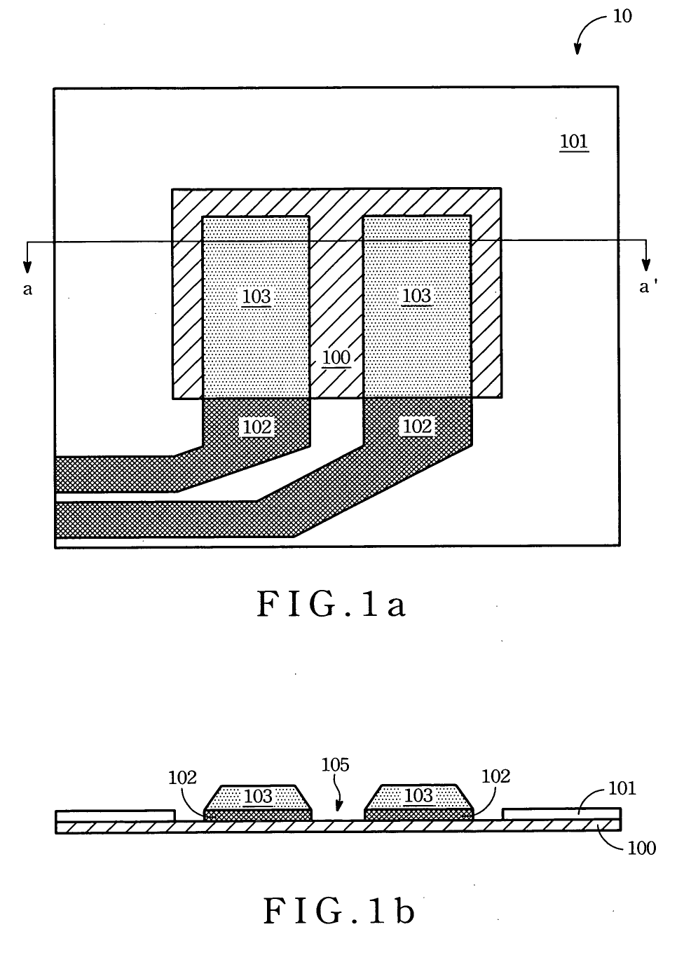

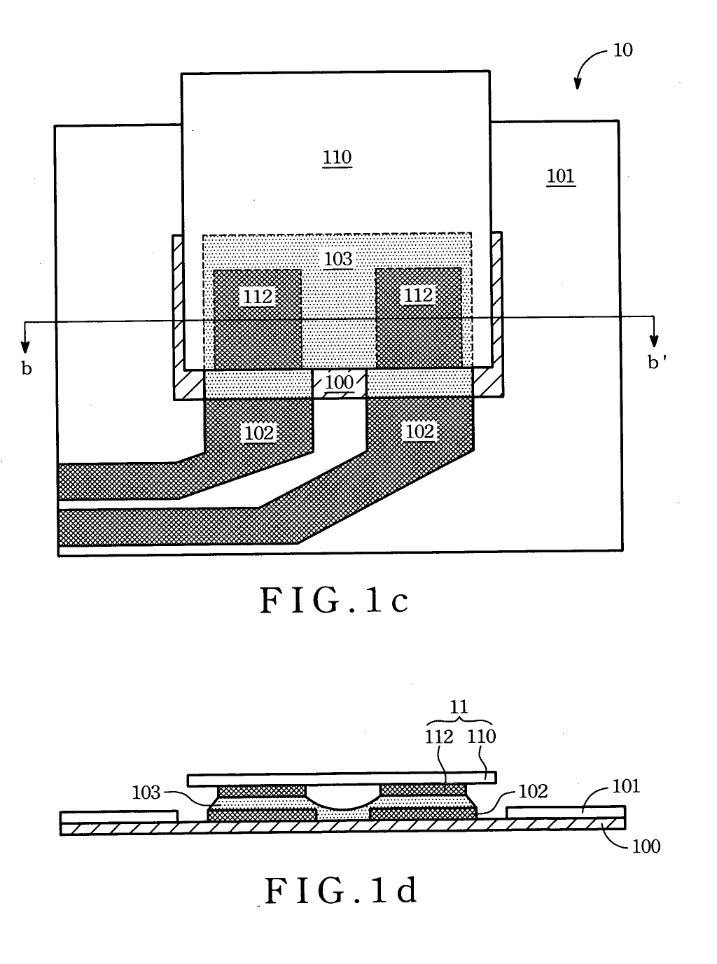

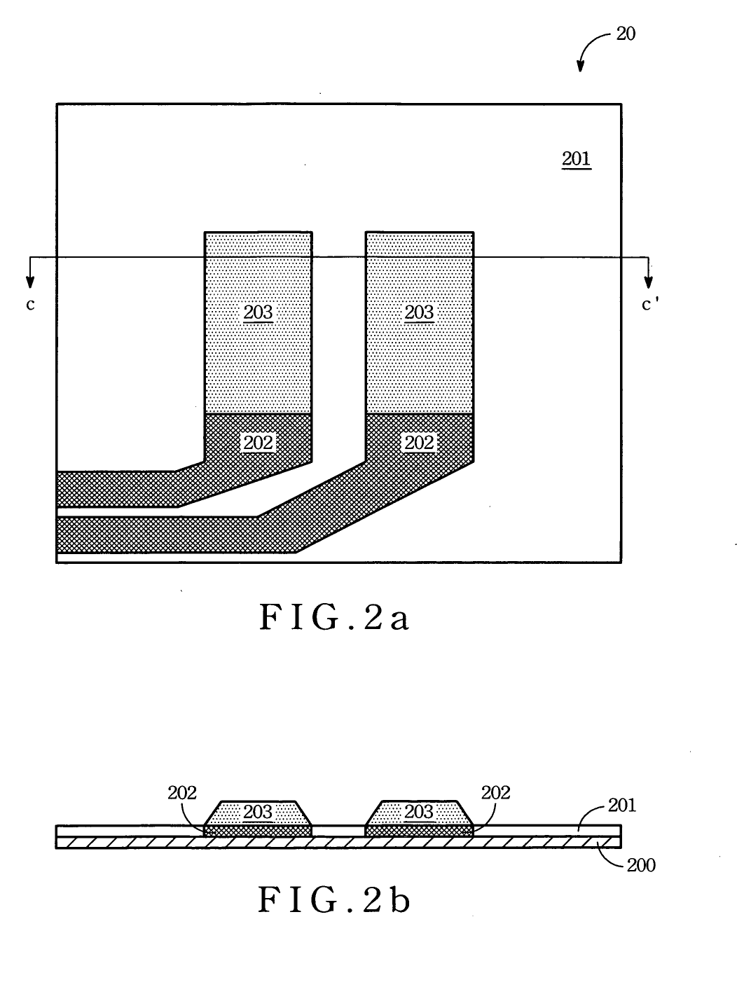

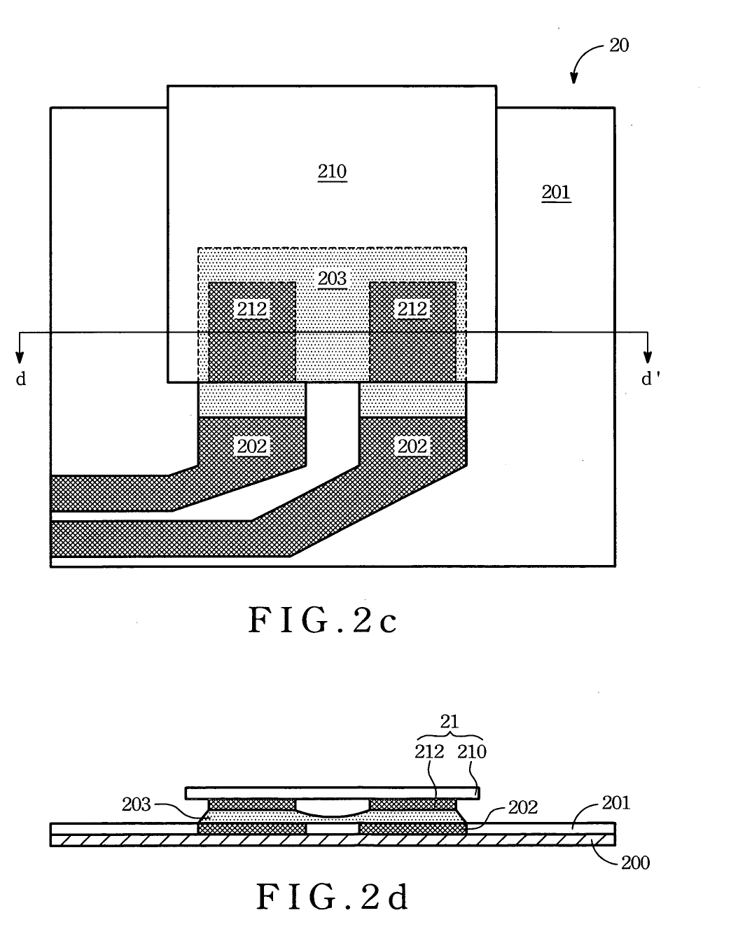

### DETAILED DESCCRIPTIONS OF THE PREFERRED EMBODIMENT

The object of the present invention is to provide an FPC that can prevent the adjacent pads from occurring short circuit. In the present invention, a rib is included to resist possible overflowing of the tin grease between the pads, and thereby possible short circuiting between two adjacent pads can be avoided. Detailed description of the present invention will be shown in follow.

### The First Embodiment

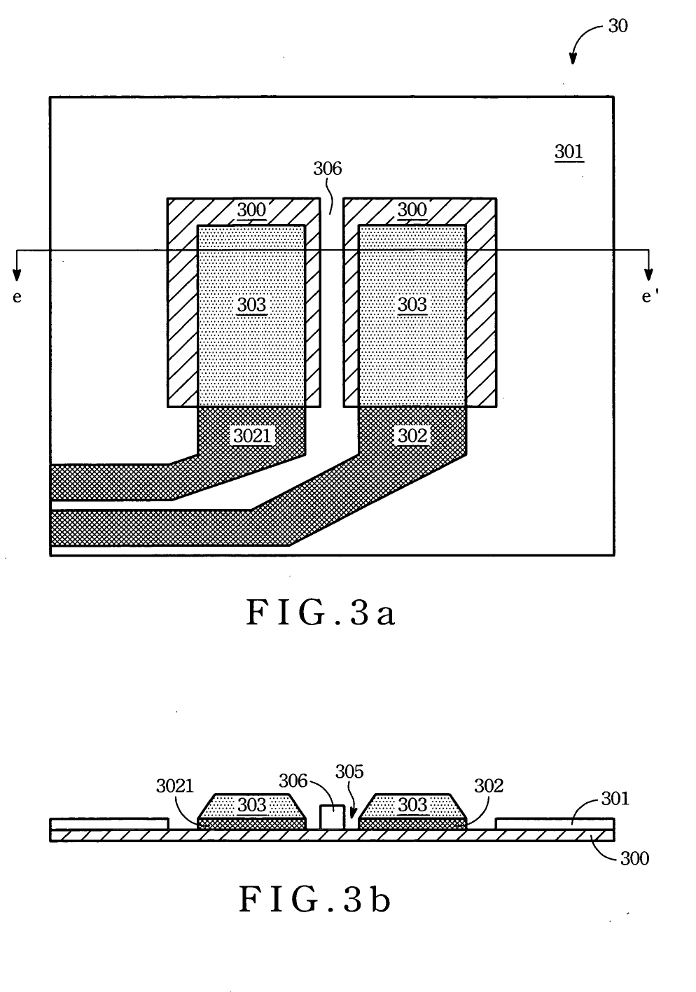

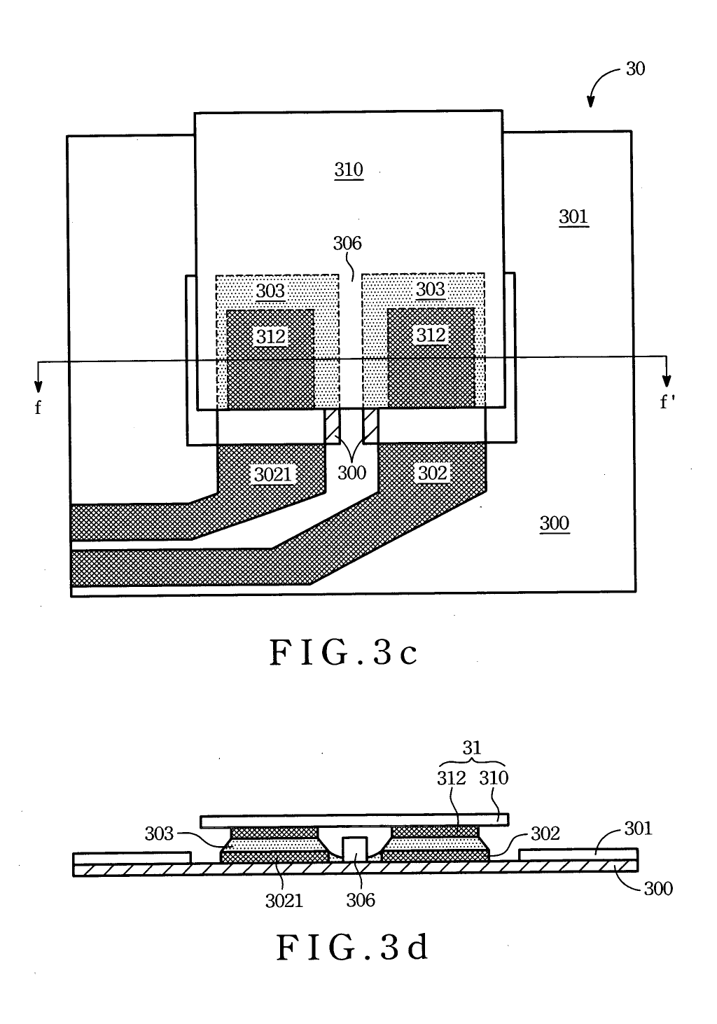

Refer to FIG. 3a˜3d for a preferred welding structure of an FPC in accordance with the present invention. As FIG. 3a and FIG. 3b showing, a frontage view and its cross sectional view of the welding structure of the FPC are shown. The welding structure 30 comprises a base board 300, a first pad 302, a second pad 3021 and a rib 306. The base board 300 forms the main portion of the FPC. The first pad 302 and the second pad 3021 are disposed on the base board 300. The second pad 3021 is set aside the first pad 302. The rib 306 is disposed on the base board 300 and set between the first pad 302 and the second pad 3021.

In the present invention, to prevent circuit diagrams on the base board 300 from being damaged by the exterior objects, the top surface of the base board 300 is usually spread by an insulation layer 301 by halftone printing or development etching.

As shown in FIG. 3b, the insulation layer 301 has a hollow opening 305 for exposing the first pad 302 and the second pad 3021. The rib 306 is disposed on the top surface of the base board 300 and between the two pads 302 and 3021. A typical design for the opening 305, as shown in FIG. 3b, can expose the adjacent first pad 302 and second pad 3021, the rib 306, and some surrounding areas of the base board 300 around the pads 302 and 3021. Once the FPC proceeds a welding with another FPC, these pads 302,3021 will be coated by respective tin greases 303 for proceeding a melt-and-weld process.

Referring to FIGS. 3c and 3d, a frontage view and its cross sectional view of the welding structure 30 of the FPC welded with a on-top FPC are shown, respectively.

As shown, after the tin greases 303 on the pads 302 3021 melt, another welding structure 31 of another FPC will be pressed on top of the welding structure 30. The on-top FPC comprises a base board 310, and pads 312 formed on the base board 310 to face the corresponding pads 303 of the welding structure 30. After the welding, the pads 312 of the welding structure 31 will be fixed to the corresponding pads 302 and 3021 through the tin greases 303.

In the present invention, by providing the rib 306 between the adjacent pads 302 and 3021 to have a thickness substantially larger than that of the insulation layer 301, the rib 306 can successfully prevent the melted tin grease 303 on the pads 302 and 3021 from overflowing sideward enough to make short circuit between the two pads 302 and 3021.

In the present invention, the rib 306 and the insulation layer 301 can be made of the same material, such as the Polyimide material. The rib 306 and the insulation layer 301 can be formed at the same time and the thickness (height) of the rib 306 is needed to be larger than that of the insulation layer 301. For example, the thickness of the rib 306 can be above 25 μm, and the distance between the rib 306 and each pad 302 or 3021 can be larger than 0.1 mm.

In the present invention, the FPC can be a flexible FPC applied to a power connection line of an electrical product. The electrical product can be an LCD and the FPC can be used to connect to the light source of the monitor of the LED.

### The Second Embodiment

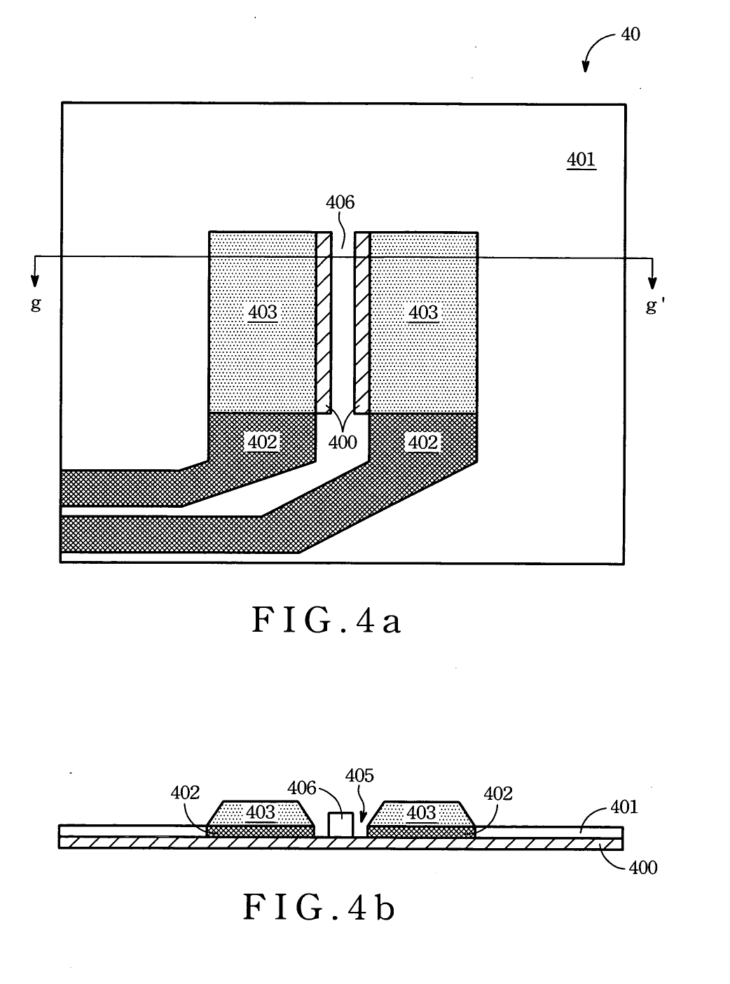

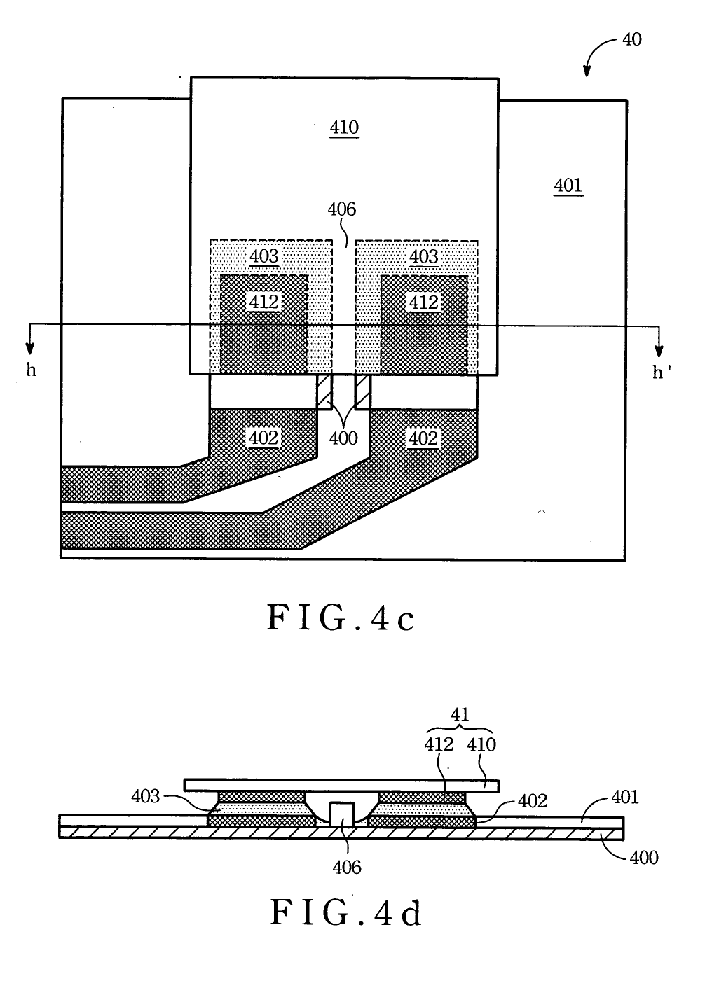

Referring to FIGS. 4a˜4d, the views of the second embodiment show that the opening 405 herein is used to expose only the pads 402 and the enclosed area between the pads 402 that includes the rib 406. In this embodiment, the welding structure 40 comprises a base board 400, an insulation layer 401, at least two pads 402, a rib 406 and tin greases 403.

As shown, the top surface of the base board 400 is coated by an insulation layer 401. The insulation layer 401 has a hollow opening 405 for exposing out the pads 402 and the rib 406 in between. The rib 406 and the insulation layer 401 can be made of the same material such as the Polyimide material. Before the FPC can proceed a welding process with another FPC, these pads 402 shall be spread by tin greases 403 for following melting welding.

Referring to FIGS. 4c and 4d, a frontage view and its sectional view along line hh′ of the welding structure 40 of the FPC with another FPC on top are shown, respectively. After the tin grease 403 on the pads 402 melts, another FPC can be pressed onto the welding structure 40. As shown, the top FPC comprises a base board 410, and the pads 412 formed under the base board 410. After a thorough welding pressing, the pads 412 of the welding structure can join firmly to the corresponding pads 402.

In the present invention, the thickness (height) of the rib 406 is larger than that of the insulation layer 401, such that the lateral flowing of the melted tin grease 403 won't flow over the top of the rib 406 and to make short circuit between two adjacent pads 4021.

To sum up, this present invention in the rib design solves the conventional welding structure of the FPC in possible short circuiting caused by the melted tin grease flow. Thereby, even in the high density pitch design of the FPC, the rib design provided by the present invention can improve the yield of the FPC welding process.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A welding structure, comprising:
aprinted circuit board (PCB);
a first pad, disposed on the PCB;
a second pad, disposed on the PCB but aside the first pad; and
a rib, disposed on the PCB, disposed between the first pad and the second pad.

2. The welding structure of claim 1, further comprising an insulation layer to cover the PCB, the insulation layer having an opening to expose the first pad, the second pad and the rib.

3. The welding structure of claim 2, wherein the opening exposes also surrounding areas of the first pad, the second pad, and the rib.

4. The welding structure of claim 2, wherein the opening exposes the first pad, the second pad and the rib.

5. The welding structure of claim 2, wherein the rib and the insulation layer are formed at the same time.

6. The welding structure of claim 2, wherein the rib and the insulation layer are made of the same material.

7. The welding structure of claim 1, wherein the rib is made of a Polyimide material.

8. The welding structure of claim 1, wherein a thickness of the rib is above 25 μm.

9. The welding structure of claim 8, wherein the thickness of the rib is larger than another thickness of the insulation layer.

10. The welding structure of claim 1, wherein a distance between the rib and the pad is larger than 0.1 mm.

11. The welding structure of claim 1, wherein the PCB comprises a flexible printed circuit (FPC) board.
